(19) United States
(12) Patent Application Publication
(10) Pub. No.: US 2025/0201731 A1
(43) Pub. Date: Jun. 19, 2025

(54) SEMICONDUCTOR DEVICE AND METHOD FOR FABRICATING THE SAME

(71) Applicant: UNITED MICROELECTRONICS CORP., Hsin-Chu City (TW)

(72) Inventors: Yi-An Shih, Changhua County (TW); Che-Wei Tsai, Kaohsiung City (TW); Da-Jun Lin, Kaohsiung City (TW); I-Ming Tseng, Kaohsiung City (TW); Chung-Sung Chiang, Kaohsiung City (TW); Yu-Chun Chen, Kaohsiung City (TW); Yu-Ping Wang, Hsinchu City (TW)

(73) Assignee: UNITED MICROELECTRONICS CORP., Hsin-Chu City (TW)

(21) Appl. No.: 18/416,854

(22) Filed: Jan. 18, 2024

(30) Foreign Application Priority Data
Dec. 15, 2023 (TW) 112149042

(51) Int. Cl. H01L 23/00

(52) U.S. Cl. CPC H01L 23/562; H01L 24/08; H01L 24/80; H01L 2224/08145; H01L 2224/80895; H01L 2224/80896

(57) ABSTRACT

A semiconductor device includes a first wafer and a second wafer. The first wafer includes a first substrate, a stress tuning structure and a first bonding structure. The stress tuning structure is disposed on the first substrate. The stress tuning structure includes a first oxide layer and a second oxide layer sequentially disposed on the first substrate, and a first refractive index of the first oxide layer is different from a second refractive index of the second oxide layer. The first bonding structure is disposed on the stress tuning structure. The second wafer includes a second substrate and a second bonding structure. The second bonding structure is disposed on the second substrate. The second bonding structure is bonded with the first bonding structure.

### BACKGROUND OF THE INVENTION

### 1. Field of the Invention

The present disclosure relates to the field of semiconductor devices, and more particularly, to a bonded semiconductor device and a method for fabricating the same.

### 2. Description of the Prior Art

A three-dimensional integrated circuit (3D IC) refers to a three-dimensional stack of chips formed by using wafer level bonding and through silicon via (TSV) technologies. In comparison with conventional two-dimensional chips, the 3D IC may have the advantages of using the space more effectively, shorter signal transmission distances between chips, and lower interconnecting resistances. As a result, the 3D ICs have gradually become the mainstream technology of power converters, low noise amplifiers, radio frequency (RF) or millimeter wave (MMW) components.

However, current 3D ICs still have problems needed to be improved. For example, in the 3D IC, the upper wafer and the lower wafer may be the same kind or different kinds of wafers. For example, both the upper wafer and the lower wafer may be logic wafers, or one of the upper wafer and the lower wafer is a logic wafer, and the other one of the upper wafer and the lower wafer is a dynamic random access memory (DRAM) wafer. Because different kinds of wafers are subjected to different fabricating processes, the wafers may accumulate different stresses so as to generate warpages of different degrees. As a result, the alignment of bonding is affected, which in turn affects the properties of the 3D ICs.

### SUMMARY OF THE INVENTION

According to one aspect of the present disclosure, a semiconductor device includes a first wafer and a second wafer. The first wafer includes a first substrate, a stress tuning structure and a first bonding structure. The stress tuning structure is disposed on the first substrate. The first bonding structure is disposed on the stress tuning structure. The stress tuning structure includes a first oxide layer and a second oxide layer sequentially disposed on the first substrate, and a first refractive index of the first oxide layer is different from a second refractive index of the second oxide layer. The second wafer includes a second substrate and a second bonding structure. The second bonding structure is disposed on the second substrate. The second bonding structure is bonded with the first bonding structure.

According to another aspect of the present disclosure, a method for fabricating a semiconductor device includes steps as follows. A first wafer is provided, in which the first wafer includes a first substrate, a stress tuning structure disposed on the first substrate and a first bonding structure disposed on the stress tuning structure, the stress tuning structure includes a first oxide layer and a second oxide layer sequentially disposed on the first substrate, and a first refractive index of the first oxide layer is different from a second refractive index of the second oxide layer. A second wafer is provided, in which the second wafer includes a second substrate and a second bonding structure disposed on the second substrate. The second bonding structure is bonded with the first bonding structure.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1, FIG. 2 and FIG. 3 are schematic cross-sectional views showing steps of a method for fabricating a semiconductor device according to an embodiment of the present disclosure.

FIG. 4 is an enlarged view of a portion A shown in FIG. 3.

FIG. 5 is a schematic cross-sectional view of a semiconductor device according to another embodiment of the present disclosure.

FIG. 6 shows an experimental result of misalignment of a semiconductor device according to a comparative example and a semiconductor device according to an example of the present disclosure.

FIG. 7 shows another experimental result of misalignment of the semiconductor device according to the comparative example and the semiconductor device according to the example of FIG. 6.

### DETAILED DESCRIPTION

In the following detailed description of the embodiments, reference is made to the accompanying drawings which form a part thereof, and in which is shown by way of illustration specific embodiments in which the disclosure may be practiced. In this regard, directional terminology, such as up, down, left, right, front, back, bottom or top is used with reference to the orientation of the Figure(s) being described. The elements of the present disclosure can be positioned in a number of different orientations. As such, the directional terminology is used for purposes of illustration and is in no way limiting. In addition, identical numeral references or similar numeral references are used for identical elements or similar elements in the following embodiments.

Hereinafter, for the description of “the first feature is formed on or above the second feature”, it may refer that “the first feature is in contact with the second feature directly”, or it may refer that “there is another feature between the first feature and the second feature”, such that the first feature is not in contact with the second feature directly.

It is understood that, although the terms first, second, etc. may be used herein to describe various elements, regions, layers and/or sections, these elements, regions, layers and/or sections should not be limited by these terms. These terms may be only used to distinguish one element, region, layer and/or section from another element, region, layer and/or section. Terms such as “first,” “second,” and other numerical terms when used herein do not imply a sequence or order unless clearly indicated by the context. Thus, a first element, region, layer and/or section discussed below could be termed a second element, region, layer and/or section without departing from the teachings of the embodiments. The terms used in the claims may not be identical with the terms used in the specification, but may be used according to the order of the elements claimed in the claims.

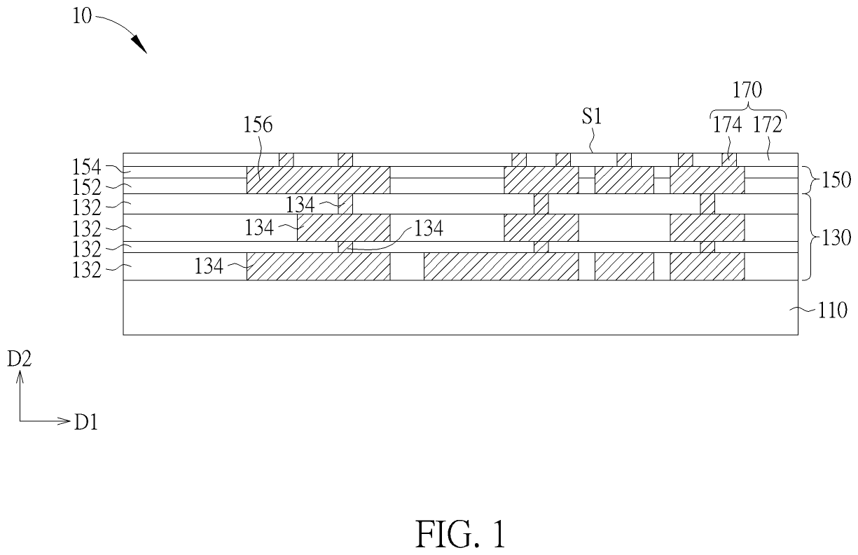

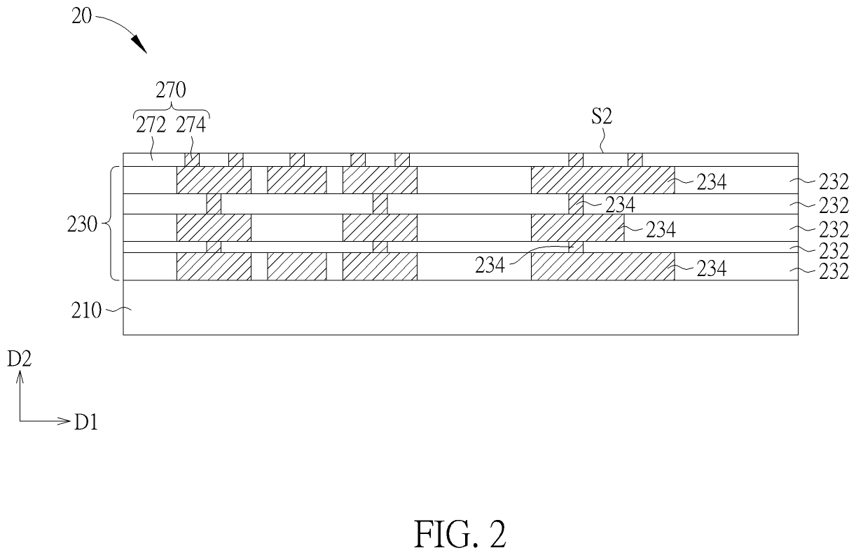

Please refer to FIG. 1 to FIG. 3, which are schematic cross-sectional views showing steps of a method for fabricating a semiconductor device according to an embodiment of the present disclosure. In FIG. 1, a first wafer 10 is provided first. The first wafer 10 includes a first substrate 110, a first interconnection structure 130 disposed on the first substrate 110, a stress tuning structure 150 disposed on the first interconnection structure 130, and a first bonding structure 170 disposed on the stress tuning structure 150. The stress tuning structure 150 includes a first oxide layer 152 and a second oxide layer 154 sequentially disposed on the first substrate 110, and metal layers 156 disposed in the first oxide layer 152 and the second oxide layer 154. A first refractive index of the first oxide layer 152 is different from a second refractive index of the second oxide layer 154.

For example, the first wafer 10 may be fabricated as follows. First, the first substrate 110 may be provided. The first substrate 110, for example, may be a silicon substrate, an epitaxial silicon substrate, a silicon carbide substrate or a silicon on insulator (SOI) substrate. The first substrate 110 may be formed with active elements (not shown) or passive elements (not shown), such as transistors, diodes, capacitors, inductors or resistors, according to actual needs, but the present disclosure is not limited thereto.

Next, a metal interconnection process may be performed to form the first interconnection layer 130 on the first substrate 110. For example, a stop layer (not shown) and an inter-metal dielectric layer 132 may be formed sequentially on the surface of the first substrate 110, and then one or more lithography and etching processes may be performed to remove a portion of the inter-metal dielectric layer 132 and a portion of the stop layer to form contact holes (not labeled). Next, a conductive material is completely filled into each of the contact holes and a planarization process such as a CMP process is performed to form metal interconnections 134 to electrically connect the active elements (not shown) or the passive elements (not shown) on the first substrate 110. The material of the inter-metal dielectric layer 132 may include silicon dioxide (SiO), silicon nitride (SiN), silicon oxynitride (SiON), silicon carbonitride (SiCN), nitrogen-doped silicon carbide (NDC), low dielectric constant (low-k) dielectric material, such as fluorinated silica glass (FSG), carbon doped silicon oxide (SiCOH), spin-on glass, porous low-k dielectric material, organic polymer dielectric material, plasma enhanced oxide, or other suitable dielectric materials. The conductive material forming the metal interconnection 134 may include a barrier layer (not shown) and a metal layer (not shown). The material of the barrier layer may include titanium (Ti), tantalum (Ta), titanium nitride (TiN), tantalum nitride (TaN) or a combination thereof. The material of the metal layer may include aluminum (Al), titanium (Ti), tantalum (Ta), tungsten (W), niobium (Nb), molybdenum (Mo), copper (Cu) or a combinations thereof, but not limited thereto. The above process may be repeated to form the first interconnection layer 130 including a plurality of combinations of the inter-metal dielectric layer 132 and the metal interconnections 134 on the first substrate 110 according to process requirements, so as to complete the back-end-of-the-line (BEOL) process. The first interconnection structure 130 may also include other circuit elements, such as capacitors, inductors, resistors and embedded memories, which are not shown for the sake of simplification.

Next, the stress tuning structure 150 may be formed on the first interconnection structure 130. For example, a stop layer (not shown), a first oxide layer 152 and a second oxide layer 154 may be formed sequentially on the surface of the first interconnection structure 130, and then one or more lithography and etching processes may be performed to remove a portion of the second oxide layer 154, a portion of the first oxide layer 152 and a portion of the stop layer to form contact holes (not labeled). Next, a conductive material is completely filled into each of the contact holes and a planarization process such as a CMP process is performed to form the metal layers 156 disposed in the first oxide layer 152 and the second oxide layer 154. The material of the first oxide layer 152 may include, for example, a plasma enhanced oxide, and the material of the second oxide layer 154 may include, for example, another plasma enhanced oxide, and the refractive indices of the two plasma enhanced oxides are different. Furthermore, the material of the first oxide layer 152 and the material of the second oxide layer 154 may both be different from the material of the inter-metal dielectric layer 132.

Alternatively, one of the materials of the first oxide layer 152 and the material of the second oxide layer 154 may be identical to the material of the inter-metal dielectric layer 132. The conductive material forming the metal layers 156 may be selected from the aforementioned conductive materials applicable to the metal interconnection 134, and is omitted herein.

Next, the first bonding structure 170 may be formed on the stress tuning structure 150. For example, a stop layer (not shown) and a first bonding dielectric layer 172 may be formed sequentially on the surface of the stress tuning structure 150, and then one or more lithography and etching processes may be performed to remove a portion of the first bonding dielectric layer 172 and a portion of the stop layer to form contact holes (not labeled). Next, a conductive material is completely filled into each of the contact holes and a planarization process such as a CMP process is performed to form the first bonding conductors 174 disposed in the first bonding dielectric layer 172. Thereby, the fabrication of the first wafer 10 is completed.

The material of the first bonding dielectric layer 172 may include a dielectric material that can perform wafer level bonding with the bonding dielectric layer of another wafer (such as the second bonding dielectric layer 272 of the second wafer 20 recited below). For example, the material of the first bonding dielectric layer 172 may be silicon dioxide, tetraethoxysilane (TEOS), silicon nitride (SiN), silicon oxynitride (SiON), silicon carbonitride (SiCN) or a plasma enhanced oxide, but not limited thereto. Furthermore, the material of the first bonding dielectric layer 172 may be different from the material of the first oxide layer 152 and may be different from the material of the second oxide layer 154. Alternatively, the material of the first bonding dielectric layer 172 may be identical to one of the material of the first oxide layer 152 and the material of the second oxide layer 154. The conductive material forming the first bonding conductors 174 may include a metal material suitable for wafer level bonding, such as copper (Cu), but not limited thereto.

Next, as shown in FIG. 2, the second wafer 20 is provided. The second wafer 20 includes a second substrate 210, a second interconnection structure 230 disposed on the second substrate 210, and a second bonding structure 270 disposed on the second interconnection structure 230.

For example, the second wafer 20 may be fabricated as follows. First, the second substrate 210 may be provided. The second substrate 210, for example, may be a silicon substrate, an epitaxial silicon substrate, a silicon carbide substrate or a silicon on insulator (SOI) substrate. The second substrate 210 may be formed with active elements (not shown) or passive elements (not shown), such as transistors, diodes, capacitors, inductors or resistors, according to actual needs, but the present disclosure is not limited thereto.

Next, a metal interconnection process may be performed to form the second interconnection structure 230 on the second substrate 210. For example, a stop layer (not shown) and an inter-metal dielectric layer 232 may be formed sequentially on the surface of the second substrate 210, and then one or more lithography and etching processes may be performed to remove a portion of the inter-metal dielectric layer 232 and a portion of the stop layer to form contact holes (not labeled). Next, a conductive material is completely filled into each of the contact holes and a planarization process such as a CMP process is performed to form metal interconnections 234 to electrically connect the active elements (not shown) or the passive elements (not shown) on the second substrate 210. The conductive material of the metal interconnection 234 may be selected from the conductive material applicable to the metal interconnection 134, and the material of the inter-metal dielectric layer 232 may be selected from the material applicable to the inter-metal dielectric layer 132, and are omitted herein. The above process may be repeated to form the second interconnection structure 230 including a plurality of combinations of the inter-metal dielectric layers 232 and the metal interconnections 234 on the second substrate 210 according to process requirements, so as to complete the BEOL process. The second interconnection structure 230 may also include other circuit elements, such as capacitors, inductors, resistors and embedded memories, which are not shown for the sake of simplification.

Next, the second bonding structure 270 may be formed on the second interconnection structure 230. For example, a stop layer (not shown) and a second bonding dielectric layer 272 may be formed sequentially on the surface of the second interconnection structure 230, and then one or more lithography and etching processes may be performed to remove a portion of the second bonding dielectric layer 272 and a portion of the stop layer to form contact holes (not labeled). Next, a conductive material is completely filled into each of the contact holes and a planarization process such as a CMP process is performed to form the second bonding conductors 274 disposed in the second bonding dielectric layer 272. For the material of the second bonding dielectric layer 272 and the conductive material of the second bonding conductors 274, references may be made to the relevant description of the first bonding dielectric layer 172 and the first bonding conductors 174, and are omitted herein. Thereby, the fabrication of the second wafer 20 is completed.

Next, the second bonding structure 270 and the first bonding structure 170 are bonded. As shown in FIG. 3, the backside of the first wafer 10 is turned to face up. Next, a bonding process such as a hybrid bonding technology is performed, in which the first bonding conductors 174 embedded in the first bonding dielectric layer 172 and the second bonding conductors 274 embedded in the second bonding dielectric layer 272 are aligned to contact each other face to face, and then a thermal treatment is performed to facilitate the formation of bonds between the first bonding dielectric layer 172 and the second bonding dielectric layer 272, and the second bonding conductors 274 and the first bonding conductors 174 are bonded through the atom diffusion of the metal in the solid state. Thereby, the fabrication of the semiconductor device 1 may be completed. In some embodiments, before performing the bonding process, the first bonding structure 170 and the second bonding structure 270 may be subjected to a surface treatment to remove impurities attached on the surface and/or modify the surface to improve the bonding. The temperature of the thermal treatment may range from 100° C. to 400° C.

Although not shown in the drawings, the method for fabricating the semiconductor device may further include other processes for fabricating a 3D IC. For example, a dielectric layer may be formed on the backside of the first wafer 10, and a plug process may be performed to form a plurality of plugs (also called through silicon vias (TSVs)) in the dielectric layer and the first substrate 110 to electrically connect with the metal interconnections 134, and a plurality of metal pads may be formed on the dielectric layer to electrically connect with the plurality of plugs. The plurality of metal pads may be served as the output/input bonding pads of the entire 3D IC (i.e., the semiconductor device 1).

The aforementioned film layers, such as the inter-metal dielectric layer 132, the metal interconnection 134, the first oxide layer 152, the second oxide layer 154, the metal layer 156, the first bonding dielectric layer 172, the first bonding conductor 174, the inter-metal dielectric layer 232, the metal interconnection 234, the second bonding dielectric layer 272, the second bonding conductor 274, may be formed by any suitable methods. For example, the methods may be, but are not limited to, molecular-beam epitaxy (MBE), chemical vapor deposition (CVD), metal organic chemical vapor deposition (MOCVD), hydride vapor phase epitaxy (HVPE) and atomic layer deposition (ALD).

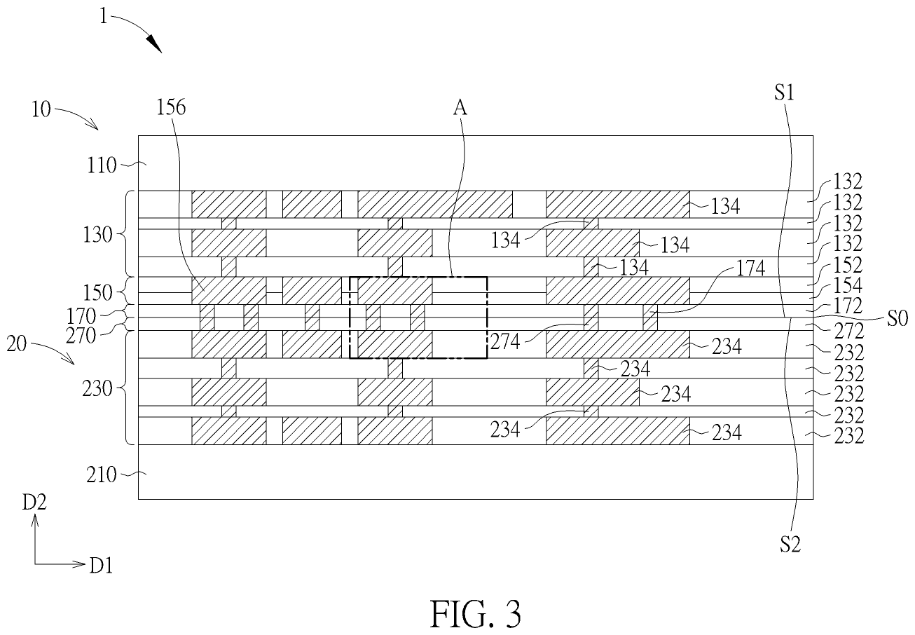

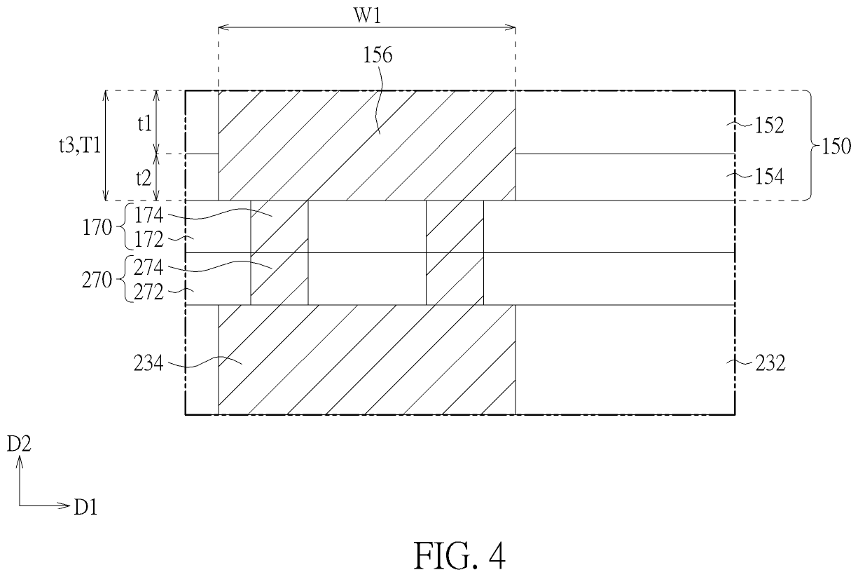

Please refer to FIG. 3 and FIG. 4 simultaneously. FIG. 3 is a schematic cross-sectional view of the semiconductor device 1 according to an embodiment of the present disclosure. FIG. 4 is an enlarged view of a portion A shown in FIG. 3. The semiconductor device 1 includes the first wafer 10 and the second wafer 20. The first wafer 10 includes the first substrate 110, the stress tuning structure 150, the first bonding structure 170, and may optionally include the first interconnection structure 130. The first interconnection structure 130 is disposed on the first substrate s 110, the stress tuning structure 150 is disposed on the first interconnection structure 130 (that is, the stress tuning structure 150 is disposed on the first substrate 110 through the first interconnection structure 130), and the first bonding structure 170 is disposed on the stress tuning structure 150. The stress tuning structure 150 includes the first oxide layer 152 and the second oxide layer 154 sequentially disposed on the first substrate 110, and the first refractive index of the first oxide layer 152 is different from the second refractive index of the second oxide layer 154.

In the embodiment, the stress tuning structure 150 includes two oxide layers (that is, the stress tuning structure 150 is a double-layer structure). However, it is exemplary, and the present disclosure is not limited thereto. In other embodiment, the number of the oxide layers of the stress tuning structure 150 may be greater than or equal to three, and the refractive indices of the oxide layers may be varied gradually along the vertical direction D2, so that the stress tuning structure 150 can provide stresses which are varied gradually.

The second wafer 20 includes the second substrate 210 and the second bonding structure 270, and may optionally include the second interconnection structure 230. The second bonding structure 270 is disposed on the second interconnection structure 230 (that is, the second bonding structure 270 is disposed on the second substrate 210 through the second interconnection structure 230), in which the second bonding structure 270 is bonded with the first bonding structure 170. Specifically, the first wafer 10 has a bonding surface S1, the second wafer 20 has a bonding surface S2, and the bonding surface S1 and the bonding surface S2 are bonded to form the bonding interface S0.

The first interconnection structure 130 may include a plurality of inter-metal dielectric layers 132 and a plurality of metal interconnections 134 disposed in the inter-metal dielectric layers 132. Herein, the number of inter-metal dielectric layers 132 is only exemplary and may be adjusted flexibly according to actual needs. The stress tuning structure 150 may further include the metal layers 156 disposed in the first oxide layer 152 and the second oxide layer 154. The first bonding structure 170 may include the first bonding dielectric layer 172 and the first bonding conductors 174 disposed through the first bonding dielectric layer 172, and the first bonding conductors 174 directly contact the metal layers 156. In other words, the stress tuning structure 150 is directly adjacent to the first bonding structure 170 in the present disclosure. It may also be regarded that the inter-metal dielectric layer of the interconnection structure of a general semiconductor device closest to the bonding structure is changed from a single-layer structure (single material) to a multi-layer structure (a structure with two or more layers; two or more materials), which may provide the effect of adjusting stress.

The second interconnection structure 230 may include plurality of inter-metal dielectric layers 232 and a plurality of metal interconnections 234 disposed in the inter-metal dielectric layers 232. Herein, the number of the inter-metal dielectric layers 232 is only exemplary and may be flexibly adjusted according to actual needs. The second bonding structure 270 may include the second bonding dielectric layer 272 and the second bonding conductors 274 disposed through the second bonding dielectric layer 272. The second bonding conductors 274 are bonded (directly contacted) with the first bonding conductors 174.

In the present disclosure, the first refractive index is different from the second refractive index, so that the first oxide layer 152 and the second oxide layer 154 have different compressive stresses or tensile stresses. According to an embodiment of the present disclosure, when the refractive index is larger, the compressive stress is larger. For example, when the refractive index of the first oxide layer 152 or the second oxide layer 154 is 1.455, the magnitude of the compressive stress may be 61 Mpa. When the refractive index of the first oxide layer 152 or the second oxide layer 154 is 1.461, the magnitude of the compressive stress may be 126 Mpa. When the refractive index of the first oxide layer 152 or the second oxide layer 154 is 1.475, the magnitude of the compressive stress may be 185 Mpa. However, the aforementioned refractive indices and the magnitudes of the compressive stresses are only exemplary, and the present disclosure is not limited thereto. The refractive indices of the materials forming the first oxide layer 152 and the second oxide layer 154 may be adjusted according to actual needs, so that the first oxide layer 152 and the second oxide layer 154 can provide different compressive stresses or tensile stresses.

In the present disclosure, with different numerical combinations of the first refractive index and the second refractive index, and with different thickness combinations of the first oxide layer 152 and the second oxide layer 154, the stress provided by the overall stress tuning structure 150 may be controlled, which is favorable for improving the flatness of the bonding surface S1 of the first wafer 10 and the flatness of the bonding surface S2 of the second wafer 20 or allowing the bonding surface S1 of the first wafer 10 and the bonding surface S2 of the second wafer 20 to fit with each other better, so that the alignment error may be reduced and the properties of the semiconductor device 1 may be improved. For example, when the first wafer 10 is not disposed with the stress tuning structure 150 (that is, the first oxide layer 152 and the second oxide layer 154 shown in FIG. 3 are replaced by the inter-metal dielectric layer 132), the bonding surface S1 may generate warpage, such as concave upward slightly or protrude downward slightly, due to process stress. With the stress tuning structure 150, the flatness of the bonding surface S1 may be improved. As another example, when the bonding surface S2 of the second wafer 20 generate the warpage which concave downward slightly due to the process stress, the stress provided by the stress tuning structure 150 may be controlled to allow the bonding surface S1 of the first wafer 10 to generate the warpage which protrudes downward slightly, so that the convex bonding surface S1 and the concave bonding surface S2 may fit with each other better.

In FIG. 4, the stress tuning structure 150 has a thickness T1 in the vertical direction D2, and the thickness T1 may range from 2000 angstroms to 4000 angstroms. The first oxide layer 152 has a first sub-thickness t1 in the vertical direction D2, the second oxide layer 154 has a second sub-thickness t2 in the vertical direction D2, and the ratio of the second sub-thickness t2 to the first sub-thickness t1 (t2/t1) may range from 0.25 to 4. For example, the first sub-thickness t1 may range from 20% to 80% of the thickness T1 (i.e., 20%×T1≤t1≤80%×T1), and the second sub-thickness t2 may range from 20% to 80% of the thickness T1 (i.e., 20%×T1≤ t2≤80%×T1). The first refractive index may range from 1.455 to 1.475. The absolute value of the difference between the second refractive index and the first refractive index may range from 0.006 to 0.02 (i.e., 0.006≤| second refractive index-first refractive index|≤0.02). When the ratio of the second sub-thickness t2 to the first sub-thickness t1, the first refractive index and the second refractive index satisfy the aforementioned relationships, the effect of reducing alignment error can be more significant.

According to an embodiment of the present disclosure, the second refractive index may be greater than the first refractive index. Therefore, among the first oxide layer 152 and the second oxide layer 154, the second oxide layer 154 that is closer to the first bonding structure 170 can provide a greater compressive stress, which is beneficial to improve the fit tightness between the bonding surfaces S1 and S2.

According to an embodiment of the present disclosure, the thickness T1 may be equal to the sum of the first sub-thickness t1 and the second sub-thickness t2 (i.e., T1=t1+t2). When the stress tuning structure 150 further includes a stop layer (not shown) disposed between the first oxide layer 152 and the first interconnection structure 130, the thickness T1 may be equal to the sum of the first sub-thickness t1, the second sub-thickness t2 and the thickness of the stop layer in the vertical direction D2.

Each of the metal layers 156 has a third sub-thickness t3 in the vertical direction D2, and the third sub-thickness t3 may be equal to the thickness T1 (i.e., t3=T1). Each of the metal layers 156 has a width W1 in the horizontal direction D1, and the width W1 may be fixed along the vertical direction D2. The aforementioned vertical direction D2 may be, for example, parallel to the normal direction (not shown) of the first substrate 110, and the horizontal direction D1 may be perpendicular to the vertical direction D2.

According to an embodiment of the present disclosure, the third sub-thickness t3 may be equal to the sum of the first sub-thickness t1 and the second sub-thickness t2 (i.e., t3=t1+t2). When the stress tuning structure 150 further includes a stop layer (not shown) disposed between the first oxide layer 152 and the first interconnection structure 130, the third sub-thickness t3 may be equal to the sum of the first sub-thickness t1, the second sub-thickness t2 and the thickness of the stop layer in the vertical direction D2.

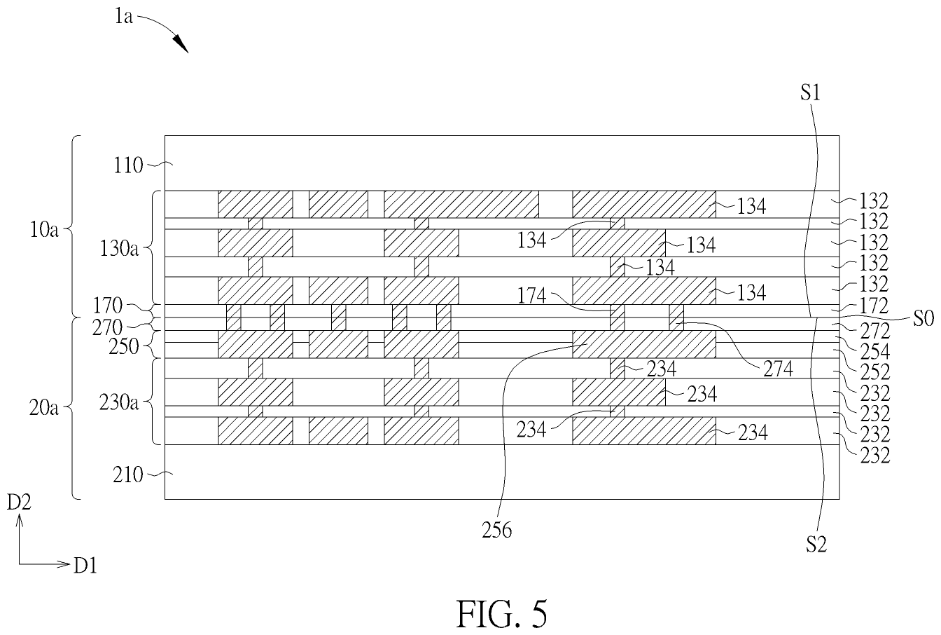

FIG. 5 is a schematic cross-sectional view of a semiconductor device 1a according to another embodiment of the present disclosure. The semiconductor device 1a includes a first wafer 10a and a second wafer 20a. The first wafer 10a includes a first substrate 110 and a first bonding structure 170, and may optionally include a first interconnection structure 130a. The second wafer 20a includes a second substrate 210, a stress tuning structure 250, a second bonding structure 270, and may optionally include a second interconnection structure 230a. The stress tuning structure 250 includes a first oxide layer 252 and a second oxide layer 254 sequentially disposed on the second substrate 210, and the metal layers 256 are disposed in the first oxide layer 252 and the second oxide layer 254, and the first refractive index of the first oxide layer 252 is different from the second refractive index of the second oxide layer 254. The main difference between the semiconductor device 1a and semiconductor device 1 is that the stress tuning structure 150 of the semiconductor device 1 is disposed on the first wafer 10 located above, while the stress tuning structure 250 of the semiconductor device 1a is disposed on the second wafer 20a located below. In addition, the number of the inter-metal dielectric layers 132 of the first interconnection structure 130a is different from the number of the inter-metal dielectric layers 132 of the first interconnection structure 130, and the number of the inter-metal dielectric layer 232 of the second interconnection structure 230a is different from the number of the inter-metal dielectric layer 232 of the second interconnection structure 230. With the second wafer 20a being disposed with the stress tuning structure 250, it is favorable for improving the flatness of the bonding surface S2, or to allow the bonding surface S2 to generate the warpage opposite to the warpage of the bonding surface S1, so as to allow the bonding surfaces S1 and S2 fit with each other better. For other details of the semiconductor device 1a, references may be made to the relevant description of the semiconductor device 1. Furthermore, in the semiconductor devices 1 and 1a, only one of the upper wafer (i.e., the first wafer 10 or 10a) and the lower wafer (i.e., the second wafer 20 or 20a) is disposed with the stress tuning structure (i.e., the stress tuning structure 150 or 250), which is exemplary, and the present disclosure is not limited thereto. In other embodiment, both the upper wafer and the lower wafer may be disposed with the stress tuning structure, thereby the flatness of the bonding surfaces of the upper wafer and the lower wafer may be improved. Furthermore, since the semiconductor devices 1 and 1a are applied to the field of wafer level bonding, both the first wafer 10 or 10a and the second wafer 20 or 20a may be wafer products, and each of the first wafer 10 or 10a and the second wafer 20 or 20a may have a plurality of corresponding dies, or one of the first wafer 10 or 10a and the second wafer 20 or 20a is a wafer product and the other is an interposer.

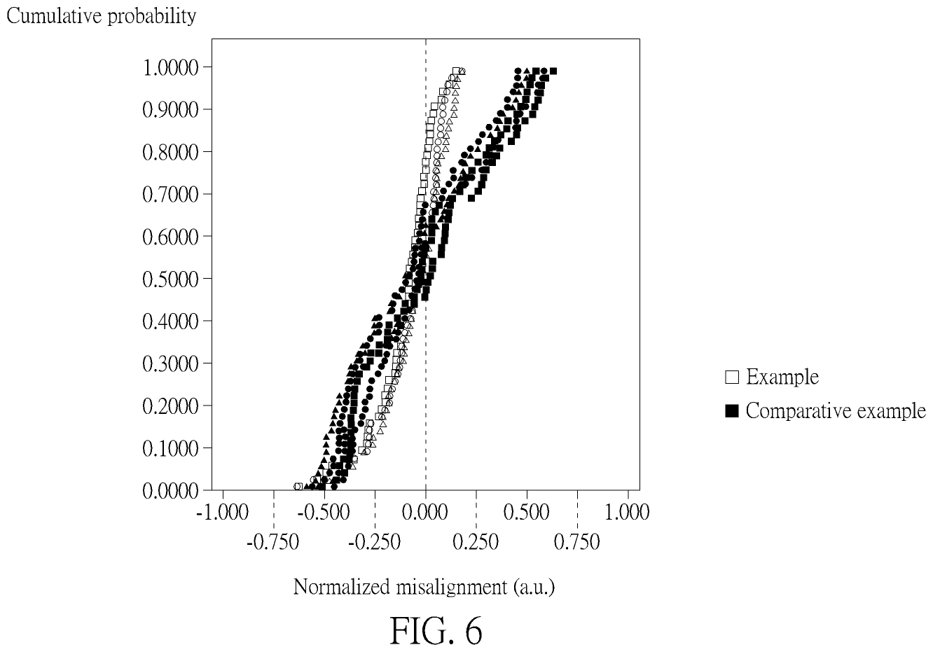

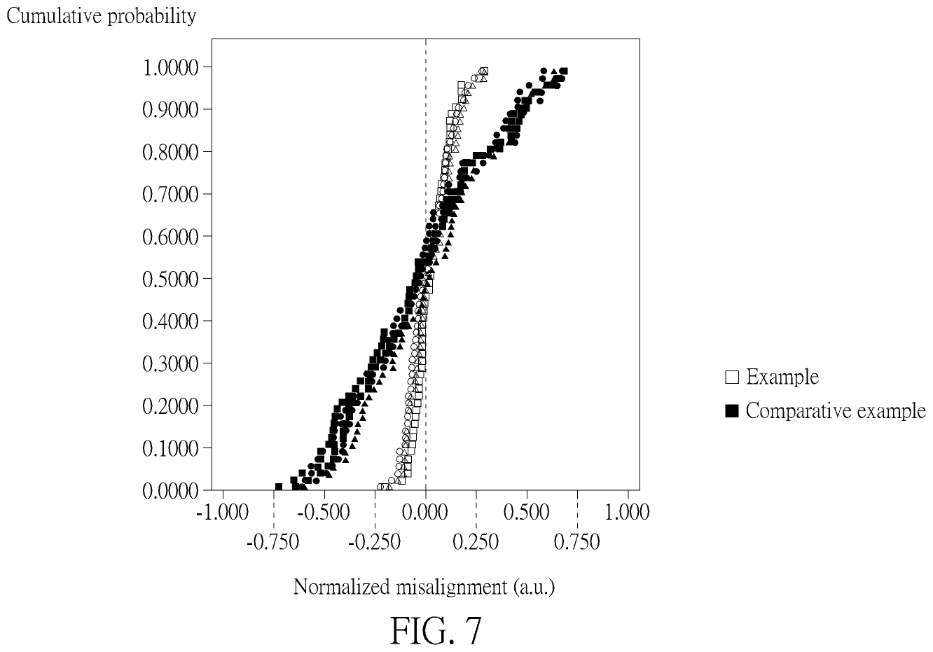

Please refer to FIG. 6 and FIG. 7. FIG. 6 shows an experimental result of misalignment of a semiconductor device according to a comparative example and a semiconductor device according to an example of the present disclosure. FIG. 7 shows another experimental result of misalignment of the semiconductor device according to the comparative example and the semiconductor device according to the example of FIG. 6. In FIG. 6 and FIG. 7, the structure of the semiconductor device according to the example of the present disclosure may refer to the structure of the semiconductor device 1 shown in FIG. 3. The difference between the semiconductor devices of the comparative example and the example is that the first oxide layer and the second oxide layer of the example is replaced by the inter-metal dielectric layer of the first interconnection structure in the comparative example. In FIG. 6, the vertical coordinate represents the cumulative probability, and the horizontal coordinate represents the normalized misalignment of the first wafer and the second wafer in the X direction (such as the horizontal direction D1). In FIG. 7, the vertical coordinate represents the cumulative probability, and the horizontal coordinate represents the normalized misalignment of the first wafer and the second wafer in the Y direction (such as another horizontal direction perpendicular to the horizontal direction D1). As shown in FIG. 6, the normalized misalignment of the comparative example in the X direction is about 1, while the normalized misalignment of the example in the X direction is about 0.625. As shown in FIG. 7, the normalized misalignment of the comparative example in the Y direction is about 1.5, while the normalized misalignment of the example in the Y direction is about 0.5. Compared with the comparative example, the example according to the present disclosure can greatly reduce the misalignment, which is beneficial to reducing the alignment error.

Compared with the prior art, the semiconductor device according to the present disclosure includes a stress tuning structure. By controlling the stress provided by the stress tuning structure, it is beneficial to improve the flatness of the bonding surfaces of the upper wafer and the lower wafer and/or allow the bonding surfaces of the upper wafer and the lower wafer to fit with each other better. Therefore, the alignment error may be reduced and the bonding quality may be improved, so as to improve the properties of the semiconductor device.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a first wafer, comprising:
a first substrate;
a stress tuning structure disposed on the first substrate, wherein the stress tuning structure comprises a first oxide layer and a second oxide layer sequentially disposed on the first substrate, and a first refractive index of the first oxide layer is different from a second refractive index of the second oxide layer; and
a first bonding structure disposed on the stress tuning structure; and
a second wafer, comprising:
a second substrate; and
a second bonding structure disposed on the second substrate, wherein the second bonding structure is bonded with the first bonding structure.

2. The semiconductor device of claim 1, wherein the stress tuning structure has a thickness in a vertical direction, and the thickness ranges from 2000 angstroms to 4000 angstroms.

3. The semiconductor device of claim 1, wherein the first oxide layer has a first sub-thickness in a vertical direction, the second oxide layer has a second sub-thickness in the vertical direction, and a ratio of the second sub-thickness to the first sub-thickness ranges from 0.25 to 4.

4. The semiconductor device of claim 1, wherein the first refractive index ranges from 1.455 to 1.475.

5. The semiconductor device of claim 1, wherein an absolute value of a difference between the second refractive index and the first refractive index ranges from 0.006 to 0.02.

6. The semiconductor device of claim 1, wherein the second refractive index is greater than the first refractive index.

7. The semiconductor device of claim 1, wherein the stress tuning structure has a thickness in a vertical direction, the stress tuning structure further comprises a metal layer disposed in the first oxide layer and the second oxide layer, the metal layer has a third sub-thickness in the vertical direction, and the third sub-thickness is equal to the thickness of the stress tuning structure.

8. The semiconductor device of claim 7, wherein the metal layer has a width in a horizontal direction, and the width is fixed along the vertical direction.

9. The semiconductor device of claim 7, wherein the first bonding structure comprises a first bonding dielectric layer and a first bonding conductor disposed through the first bonding dielectric layer, and the first bonding conductor directly contacts the metal layer.

10. The semiconductor device of claim 9, wherein a material of the first bonding dielectric layer is different from a material of the first oxide layer, and the material of the first bonding dielectric layer is different from a material of the second oxide layer.

11. A method for fabricating a semiconductor device, comprising:
providing a first wafer, wherein the first wafer comprises a first substrate, a stress tuning structure disposed on the first substrate and a first bonding structure disposed on the stress tuning structure, the stress tuning structure comprises a first oxide layer and a second oxide layer sequentially disposed on the first substrate, and a first refractive index of the first oxide layer is different from a second refractive index of the second oxide layer;
providing a second wafer, wherein the second wafer comprises a second substrate and a second bonding structure disposed on the second substrate; and
bonding the second bonding structure with the first bonding structure.

12. The method of claim 11, wherein the stress tuning structure has a thickness in a vertical direction, and the thickness ranges from 2000 angstroms to 4000 angstroms.

13. The method of claim 11, wherein the first oxide layer has a first sub-thickness in a vertical direction, the second oxide layer has a second sub-thickness in the vertical direction, and a ratio of the second sub-thickness to the first sub-thickness ranges from 0.25 to 4.

14. The method of claim 11, wherein the first refractive index ranges from 1.455 to 1.475.

15. The method of claim 11, wherein an absolute value of a difference between the second refractive index and the first refractive index ranges from 0.006 to 0.02.

16. The method of claim 11, wherein the second refractive index is greater than the first refractive index.

17. The method of claim 11, wherein the stress tuning structure has a thickness in a vertical direction, the stress tuning structure further comprises a metal layer disposed in the first oxide layer and the second oxide layer, the metal layer has a third sub-thickness in the vertical direction, and the third sub-thickness is equal to the thickness of the stress tuning structure.

18. The method of claim 17, wherein the metal layer has a width in a horizontal direction, and the width is fixed along the vertical direction.

19. The method of claim 17, wherein the first bonding structure comprises a first bonding dielectric layer and a first bonding conductor disposed through the first bonding dielectric layer, and the first bonding conductor directly contacts the metal layer.

20. The method of claim 19, wherein a material of the first bonding dielectric layer is different from a material of the first oxide layer, and the material of the first bonding dielectric layer is different from a material of the second oxide layer.
